(19) United States
(12) Patent Application Publication
(10) Pub. No.: US 2006/0141660 A1
(43) Pub. Date: Jun. 29, 2006

(54) CMOS image sensor and method for fabricating the same

(76) Inventor: Chang Eun Lee, Seoul (KR)

Correspondence Address: MCKENNA LONG & ALDRIDGE LLP;Song K. Jung, 1900 K Street, N.W., Washington, DC, 20006, US

(21) Appl. No.: 11/315,147

(22) Filed: Dec. 23, 2005

(30) Foreign Application Priority Data
Dec. 24, 2004 (KR) 10-2004-0112058

(51) Int. Cl. H01L 21/00

(52) U.S. Cl. 438/70; 438/57; 438/65

(57) ABSTRACT

A CMOS image sensor and a method for fabricating the same prevent a lifting phenomenon of a microlens. The CMOS image sensor includes a semiconductor substrate structure in which at least one photodiode is disposed, an insulating interlayer formed on the semiconductor substrate structure, a patterned metal layer formed on the insulating interlayer, an oxide layer formed on the insulating interlayer including the patterned metal layer, a passivation layer formed on the oxide layer, and at least one microlens formed in direct contact with the oxide layer, wherein the oxide layer and the passivation layer are etched to form a plurality of openings that correspond to the at least one microlens.

### CROSS-REFERENCE TO RELATED APPLICATIONS

This application claims the benefit of Korean Patent Application No. 10-2004-0112058, filed on Dec. 24, 2004, which is hereby incorporated by reference for all purposes as if fully set forth herein.

### BACKGROUND OF THE INVENTION

1. Field of the Invention

The present invention relates to a CMOS image sensor and a method for fabricating the same. Although the present invention is suitable for a wide scope of applications, it is particularly suitable for a CMOS image sensor, and a method for fabricating the same, that prevents a lifting phenomenon of a microlens.

2. Discussion of the Related Art

Image sensors are semiconductor devices for converting an optical image into an electrical signal and include charge-coupled devices and complementary metal-oxide-semiconductor (CMOS) image sensors. A general charge-coupled device includes an array of photodiodes converting light signals into electrical signals. Charge-coupled devices have the disadvantages of a complicated driving method, high power consumption, and a complicated fabrication process requiring a multi-phased photo process. In a charge-coupled device, integration of complementary circuitry, such as a control circuit, a signal processor, and an analog-to-digital converter, into a single-chip device is difficult. Development of compact-sized or thin products, such as digital still cameras and digital video cameras, is thereby hindered when using such image sensors.

CMOS image sensors, on the other hand, adopt CMOS technology using a control circuit and a signal processing circuit as a peripheral circuit and adopt switching technology which allows outputs to be sequentially detected using MOS transistors that correspond to a number of arrayed pixels. An image is thereby detected. Accordingly, a CMOS image sensor uses CMOS fabrication technology, i.e., a simple fabrication method using fewer photolithography steps, enabling an advantageous device exhibiting low power consumption.

In the aforementioned CMOS image sensor, typically, the photodiode is the active device which forms an optical image based on incident light signals. The photodiode forms the optical image by generating electrical signals according to the intensity and wavelength or color of incident light. In such a CMOS image sensor, wherein each photodiode senses incident light and the corresponding CMOS logic circuit converts the sensed light into an electrical signal according to input wavelength, the photosensitivity of the photodiode increases as more light is able to reach the photodiode. Enhanced photosensitivity results from an increase in the levels of sensed light and corresponds to the light-receiving capability of the active device. One way of enhancing the photosensitivity of a CMOS image sensor is to improve its “fill factor,” i.e., the degree of surface area covered by the photodiodes versus the entire surface area of the image sensor. The fill factor is improved by increasing the area responsive to incident light, i.e., the photo-sensing portion. However, increasing the photo-sensing portion is limited by the required presence of the logic circuit portion.

Therefore, a device having a material exhibiting excellent light transmittance, such as a convex microlens having a predetermined curvature for refracting incident light, may be provided to redirect any light that may be incident to the image sensor outside the immediate area of the photodiodes. The device may be provided to concentrate and focus the incident light on one or more of the photodiodes themselves. That is, the incident light, striking the surface of the convex structure of the microlens while in parallel to the optical axis of the microlens, is refracted by the microlens according to the curvature of the convex microlens, to become focused at a predetermined point along the optical axis. The microlens may be formed of a photoresist material deposited on a nitride layer, which serves as a passivation layer. However, there are difficulties in achieving good adhesion between the microlens and the nitride layer.

Referring to FIG. 1, a CMOS image sensor according to the related art is constructed on a semiconductor substrate structure including a series of epitaxial layers separating a plurality of photodiodes, i.e., a red photodiode 11, a green photodiode 13, and a blue photodiode 15. Each respective photodiode receives each light signal to form a color image. The semiconductor substrate structure includes a first epitaxial layer 10 in which the red photodiode 11 is formed. The structure also includes a second epitaxial layer 12, formed on the first epitaxial layer 10 including the red photodiode 11, in which the green photodiode 13 is formed, and a third epitaxial layer 14, formed on the second epitaxial layer 12 including the green photodiode 13, in which the blue photodiode 15 is formed. A shallow-trench-isolation region 16 is formed in the third epitaxial layer 14. An insulating interlayer 17 is formed on the third epitaxial layer 14 and is selectively etched to form a via 18. A patterned metal layer is then formed on the insulating interlayer 17. A pad 21 connected to a metal line (not shown) is formed on the insulating interlayer 17 by patterning a metal layer deposited on the insulating interlayer 17. To protect the device from moisture and minor external impact, a first insulating layer 19, which may be made of oxide, is formed over the insulating layer 17 including the pad 21. A second insulating layer 20, which may be made of nitride, is formed on the first insulating layer 19. Upper surfaces of the patterned metal layer are exposed by selectively etching the second and first insulating layers 20 and 19. The metal, e.g., the pad 21, undergoes a thermal treatment.

A plurality of microlenses 22, each formed of a photoresist material, is formed on the second insulating layer 20, which serves as a passivation layer on the first insulating layer 19. The second insulating layer 20 may be made of a nitride, and the first insulating layer 19 may be made of an oxide. Accordingly, the microlens 22 may become lifted, due to a state of full or partial non-adhesion. This state is due to poor or defective adhesion of the photoresist material of the microlens to the material, which may be nitride, of the second insulating layer 20. Such lifting causes defective pixels and a reduced yield. Also, the respective microlenses are formed at fixed intervals on an upper surface of the second insulating layer 20, such that the presence of these fixed intervals or inter-microlens gaps contribute to the lifting phenomenon.

### SUMMARY OF THE INVENTION

Accordingly, the present invention is directed to a CMOS image sensor and a method for fabricating the same that substantially obviates one or more problems due to limitations and disadvantages of the related art.

An advantage of the present invention is to provide a CMOS image sensor, and a method for fabricating the same, which prevents a microlens from becoming lifted.

Another advantage of the present invention is to provide a CMOS image sensor, and a method for fabricating the same, which improves yield.

Another advantage of the present invention is to provide a CMOS image sensor, and a method for fabricating the same, which facilitates improved adhesion of a microlens.

Another advantage of the present invention is to provide a CMOS image sensor, and a method for fabricating the same, which prevents a microlens lifting phenomenon by forming the microlens on an oxide layer after selectively etching a nitride layer used as a passivation layer.

Additional features and advantages of the invention will be set forth in the description which follows, and in part will be apparent from the description, or may be learned by practice of the invention. The objectives and other advantages of the invention will be realized and attained by the structure and method particularly pointed out in the written description and claims hereof as well as the appended drawings.

To achieve these and other advantages, and in accordance with the purpose of the invention, as embodied and broadly described, a CMOS image sensor includes a semiconductor substrate structure in which at least one photodiode is disposed, an insulating interlayer formed on the semiconductor substrate structure, a patterned metal layer formed on the insulating interlayer, an oxide layer formed on the insulating interlayer including the patterned metal layer, a passivation layer formed on the oxide layer, and at least one microlens formed in direct contact with the oxide layer, wherein the oxide layer and the passivation layer are etched to form a plurality of openings that correspond to the at least one microlens.

In another aspect of the present invention, a method for fabricating a CMOS image sensor includes forming an insulating interlayer on a semiconductor substrate structure in which at least one photodiode is disposed, forming a patterned metal layer on the insulating interlayer, forming an oxide layer on the insulating interlayer including the patterned metal layer, forming a passivation layer on the oxide layer, etching each of the oxide layer and the passivation layer to form a plurality of openings, and forming at least one microlens in at least one of the plurality of openings to be in direct contact with the oxide layer.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIG. 1 is a cross-sectional view of a CMOS image sensor according to the related art; and

FIGS. 2-6 are cross-sectional views of a CMOS image sensor fabricated by a method for fabricating a CMOS image sensor according to the present invention.

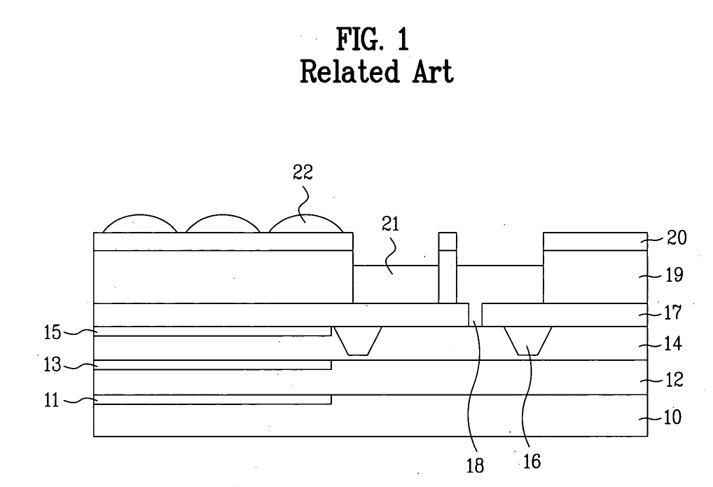

### DETAILED DESCRIPTION OF THE INVENTION

Reference will now be made in detail to exemplary embodiments of the present invention, examples of which are illustrated in the accompanying drawings. Wherever possible, like reference numbers will be used throughout the drawings to refer to the same or similar parts.

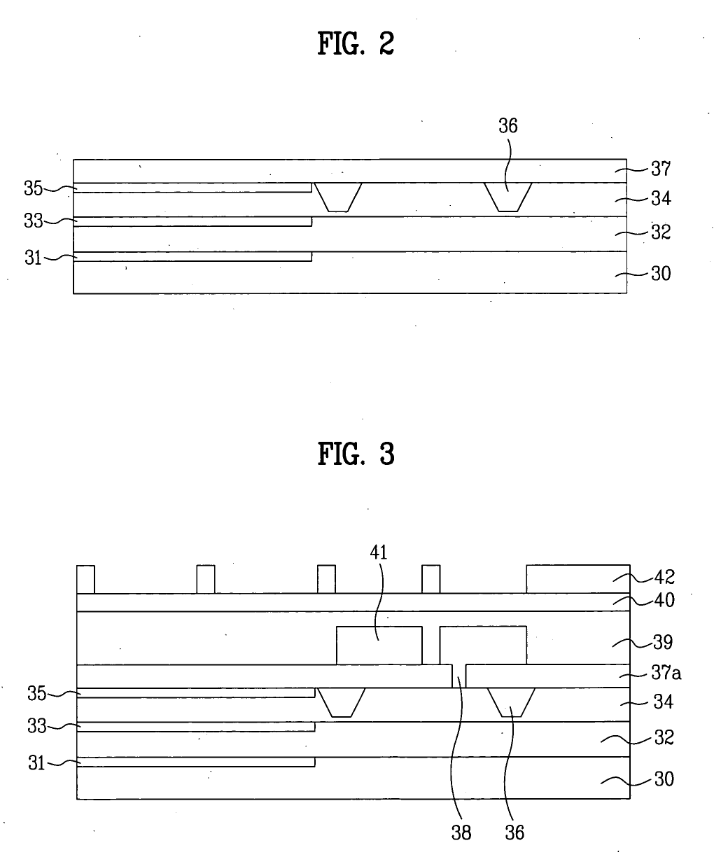

Referring to FIG. 2, a CMOS image sensor according to the present invention is constructed on a semiconductor substrate structure including a series of epitaxial layers separating a plurality of photodiodes, i.e., a red photodiode 31, a green photodiode 33, and a blue photodiode 35. Each respective photodiode receives each light signal for forming a color image. The semiconductor substrate structure includes a first epitaxial layer 30 in which the red photodiode 31 is formed. The structure also includes a second epitaxial layer 32, formed on the first epitaxial layer 30 including the red photodiode 31, in which the green photodiode 33 is formed, and a third epitaxial layer 34, formed on the second epitaxial layer 32 including the green photodiode 33, in which the blue photodiode 35 is formed. A shallow-trench-isolation region 36 is formed in the third epitaxial layer 34. An insulating interlayer 37 is formed on the third epitaxial layer 34.

Referring to FIG. 3, the insulating interlayer 37 is selectively etched to form a via 38 over which a patterned metal layer is formed. That is, a pad 41 connected to a metal line (not shown) is formed on the etched insulating interlayer 37a by patterning a metal layer deposited on the etched insulating interlayer. The pad 41 fills the via 38. To protect the device from moisture and minor external impact, a first insulating layer 39, which may be made of oxide, is formed over the etched insulating layer 37a including the pad 41. A second insulating layer 40, which may be made of nitride, is formed on the first insulating layer 39. A photoresist pattern 42, for opening a microlens formation area and a pad formation area, is formed by coating the second insulating layer 40 with photoresist and performing photolithography, i.e., an exposure and development process, with respect to the photoresist. The formation of the photoresist pattern 42 determines the separation or interval between microlenses by establishing a thickness in the pattern corresponding to a wall to be disposed between microlenses.

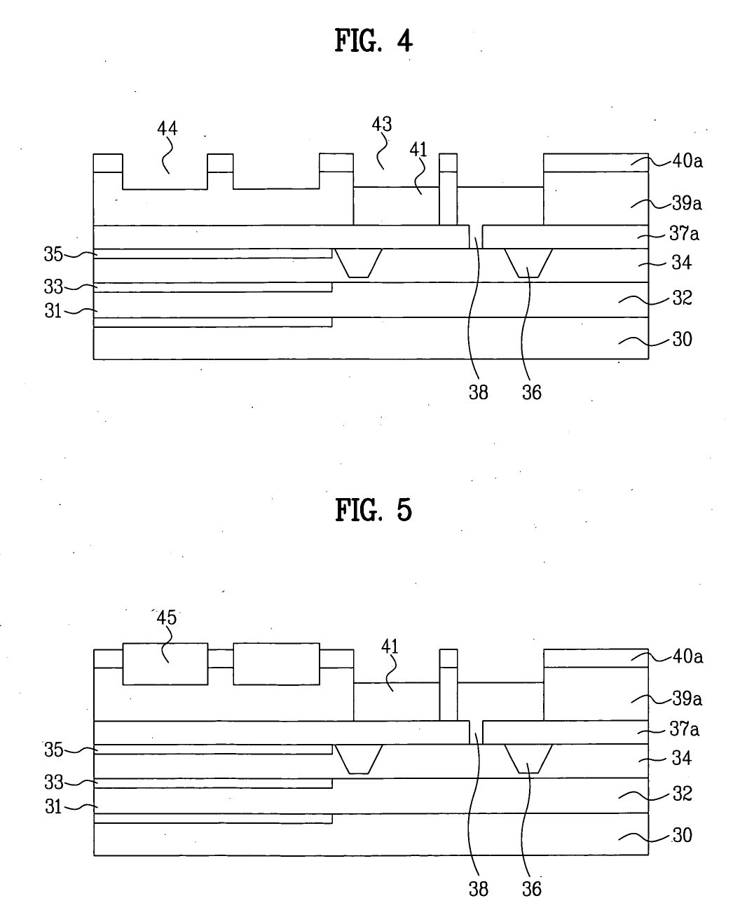

Referring to FIG. 4, the second and first insulating layers 40 and 39 are selectively etched using the photoresist pattern 42 as a mask, whereby a first opening 43 is formed to correspond to the pad formation area and a second opening 44 is formed to correspond to the microlens formation area. The first opening 43 exposes an upper surface of the pad 41. The second opening 44 has a bottom surface formed of the material of the first insulating layer 39, which enables the photoresist material for microlens formation to be in direct contact with an oxide layer rather than a nitride layer. The oxide layer is the etched first insulating layer 39a. The nitride layer is the etched second insulating layer 40a.

Referring to FIG. 5, the etched second insulating layer 40a is coated with photoresist, which is selectively exposed and developed to form a microlens pattern 45 corresponding to the second opening 44. The microlens pattern 45 fills the second opening 44 and has a top side that may be flush with an upper surface of the second insulating layer 40 or may extend above the upper surface of the second insulating layer 40.

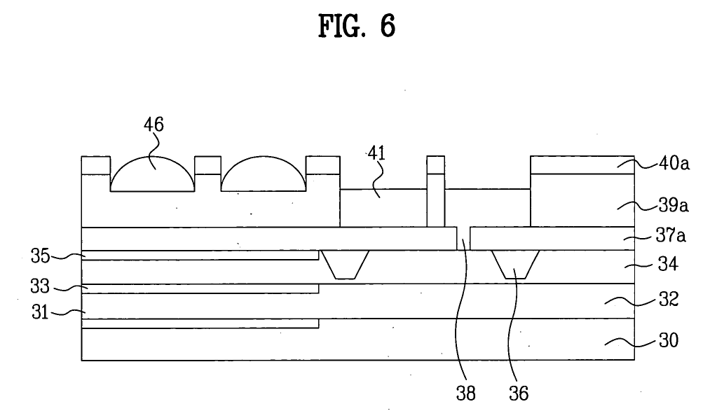

Referring to FIG. 6, a microlens 46 is formed by performing a thermal treatment and a sintering treatment to the microlens pattern 45. The inter-microlens wall established by the same patterning step for opening the pad 41 fixes a distance between each of the microlenses 46. The microlenses 46 are thus recessed to further inhibit lifting.

By adopting the CMOS image sensor and method for fabricating the same according to the present invention as described above, the microlens is formed directly on an underlying oxide layer after selectively etching a nitride passivation layer. This prevents a lifting of the microlens by enabling improved adhesion of the microlens to the lower layer. This also prevents the generation of a defective pixel, thereby improving yield. Also, since the microlens is formed by simultaneously performing the thermal and sintering treatment processes on the microlens pattern, a simplified process is enabled.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A CMOS image sensor, comprising:
a semiconductor substrate structure in which at least one photodiode is disposed;
an insulating interlayer formed on said semiconductor substrate structure;
a patterned metal layer formed on said insulating interlayer;
an oxide layer formed on said insulating interlayer including said patterned metal layer;
a passivation layer formed on said oxide layer; and
at least one microlens formed in direct contact with said oxide layer,
wherein said oxide layer and said passivation layer are etched to form a plurality of openings that correspond to said at least one microlens.

2. The CMOS image sensor of claim 1, wherein said passivation layer is formed of a nitride.

3. The CMOS image sensor of claim 1, wherein said patterned metal layer has an exposed upper surface.

4. The CMOS image sensor of claim 3, wherein the plurality of openings formed in said oxide layer and said passivation layer include openings that correspond to the exposed upper surface of said patterned metal layer.

5. The CMOS image sensor of claim 1, wherein the plurality of openings are formed by etching each of said oxide layer and said passivation layer.

6. The CMOS image sensor of claim 1, wherein the plurality of openings formed in said oxide layer and said passivation layer include at least one first opening and at least one second opening, the first opening exposing an upper surface of said patterned metal layer and the second opening having a bottom surface formed of said oxide layer.

7. The CMOS image sensor of claim 1, wherein said at least one microlens is formed in at least one of the plurality of openings formed in said oxide layer and said passivation layer.

8. The CMOS image sensor of claim 1, wherein a lower surface of said at least one microlens is adhered to said oxide layer.

9. The CMOS image sensor of claim 1, wherein said semiconductor substrate structure comprises:
a red photodiode formed in a first epitaxial layer;
a green photodiode formed in a second epitaxial layer; and
a blue photodiode formed in a third epitaxial layer,
wherein the second epitaxial layer is formed on the first epitaxial layer including said red photodiode and wherein the third epitaxial layer is formed on the second epitaxial layer including said green photodiode.

10. A method for fabricating a CMOS image sensor, comprising:
forming an insulating interlayer on a semiconductor substrate structure in which at least one photodiode is disposed;
forming a patterned metal layer on the insulating interlayer;
forming an oxide layer on the insulating interlayer including the patterned metal layer;
forming a passivation layer on the oxide layer;
etching each of the oxide layer and the passivation layer to form a plurality of openings; and
forming at least one microlens in at least one of the plurality of openings to be in direct contact with the oxide layer.

11. The method of claim 10, wherein the passivation layer is formed of a nitride.

12. The method of claim 10, wherein the patterned metal layer has an exposed upper surface.

13. The method of claim 12, wherein the plurality of openings formed in the oxide layer and the passivation layer include openings that correspond to the exposed upper surface of the patterned metal layer.

14. The method of claim 10, wherein the plurality of openings formed in the oxide layer and the passivation layer include openings that correspond to the at least one microlens.

15. The method of claim 10, wherein the plurality of openings are formed by etching each of the oxide layer and the passivation layer.

16. The method of claim 10, wherein forming the at least one microlens comprises:
forming a photoresist pattern that corresponds to the plurality of openings; and
simultaneously performing thermal and sintering treatments to the photoresist pattern to thereby form the at least one microlens.
